(19) United States
(12) Patent Application Publication
(10) Pub. No.: US 2006/0060303 A1
(43) Pub. Date: Mar. 23, 2006

(54) Plasma processing system and method

(75) Inventors: Steven T. Fink, Mesa, AZ (US); Paul Moroz, Marblehead, MA (US); Eric J. Strang, Chandler, AZ (US); Andrej S. Mitrovic, Phoenix, AZ (US)

Correspondence Address: PILLSBURY WINTHROP SHAW PITTMAN, LLP, P.O. BOX 10500, MCLEAN, VA, 22102, US

(73) Assignee: TOKYO ELECTRON LIMITED, Tokyo (JP)

(21) Appl. No.: 11/236,535

(22) Filed: Sep. 28, 2005

Related U.S. Application Data
(63) Continuation of application No. PCT/US04/01406, filed on Jan. 21, 2004.
(60) Provisional application No. 60/458,432, filed on Mar. 31, 2003.

(51) Int. Cl. B08B 6/00; H01L 21/306; C23C 16/00

(52) U.S. Cl. 156/345.29; 134/1.1; 118/723 R

(57) ABSTRACT

A plasma processing system includes a chamber containing a plasma processing region and a chuck constructed and arranged to support a substrate within the chamber in the processing region. The plasma processing system further includes at least one gas injection passage in communication with the chamber and configured to facilitate removal of particles from the chamber by passing purge gas therethrough. In one embodiment, the plasma processing system can include an electrode configured to attract or repel particles in the chamber by electrostatic force when the electrode is biased with DC or RF power. A method of processing a substrate in a plasma processing system includes removing particles in a chamber of the plasma processing system by supplying purge gas through at least one gas injection passage in communication with the chamber.

This application is a continuation of International Patent Application No. PCT/US2004/001406, filed on Jan. 21, 2004, which relies for priority upon U.S. Provisional Patent Application No. 60/458,432, filed Mar. 31, 2003, the entire contents of both of which are incorporated herein by reference in their entireties.

### BACKGROUND OF THE INVENTION

1. Field of Invention

The present invention relates to plasma processing and more particularly to removing particles from a plasma processing system during plasma processing.

2. Description of Background Information

Typically, plasma is a collection of species, some of which are gaseous and some of which are charged. Plasmas are useful in certain processing systems for a wide variety of applications. For example, plasma processing systems are of considerable use in material processing and in the manufacture and processing of semiconductors, integrated circuits, displays and other electronic devices, both for etching and layer deposition on substrates, such as, for example, semiconductor wafers.

In most plasma processing systems, solid particles, e.g., flaking from bellows, valves, or wall deposits, can be present in the plasma. During wafer processing, such particles, which range in size from sub-micron size to sizes greater than a few millimeters, can be deposited on the wafer surface where devices are being made, thereby causing damage to devices and reducing yield. Many process parameters affect generation of such particles. For example, RF and DC biases can “float” particles near the wafer and the plasma chemistry can have a greater or lesser tendency of creating wall deposits that may flake off.

### SUMMARY OF THE INVENTION

One aspect of the invention is to provide a plasma processing system that comprises a chamber containing a plasma processing region and a chuck constructed and arranged to support a substrate within the chamber in the processing region. The plasma processing system further comprises a plasma generator and at least one gas injection passage in communication with the chamber. The plasma generator is configured to generate a plasma during a plasma process in the plasma processing region and the at least one gas injection passage is configured to facilitate the removal of particles from the chamber by passing purge gas therethrough.

Another aspect of the invention is to provide a plasma processing system which comprises a chamber containing a plasma processing region and a chuck constructed and arranged to support a substrate within the chamber in the processing region. The plasma processing system further comprises a plasma generator, an electrode and at least one gas injection passage in communication with the chamber. The plasma generator is configured to generate a plasma during a plasma process in the plasma processing region. The electrode is configured to attract or repel particles in the chamber by electrostatic force when the electrode is biased with DC or RF power and the at least one gas injection passage is configured to facilitate the removal of particles from the chamber by passing purge gas therethrough.

Yet another aspect of the invention is to provide a method of processing a substrate in a plasma processing system having a chamber containing a plasma processing region in which a plasma can be generated during a plasma process. The method comprises removing particles in the chamber by supplying purge gas through at least one gas injection passageway in communication with the chamber.

### BRIEF DESCRIPTION OF THE DRAWINGS

The accompanying drawings, which are incorporated in and constitute a part of the specification, of embodiments of the invention, together with the general description given above and the detailed description of the embodiments given below, serve to explain the principles of the invention wherein:

FIG. 1A is a diagrammatic cross section of an embodiment of a plasma processing system in accordance with principles of the invention;

FIG. 1B is a diagrammatic cross section of the plasma processing system having a substrate shown in FIG. 1A, but with at least one gas injection passage transverse to a plane defined by the substrate;

FIG. 1C is a diagrammatic top view showing one arrangement of gas injection passages that could be employed in the plasma processing system shown in FIG. 1A;

FIG. 1D is a diagrammatic top view showing one arrangement of gas injection passages that could be employed in the plasma processing system shown in FIG. 1B;

FIG. 2 is a diagrammatic cross section of an alternative embodiment of the plasma processing system in accordance with principles of the invention;

FIG. 3 is a diagrammatic cross section of an alternative embodiment of the plasma processing system in accordance with principles of the invention;

FIG. 4 is a diagrammatic cross section of an alternative embodiment of the plasma processing system in accordance with principles of the invention;

FIG. 5 is a top view of the plasma processing system shown in FIG. 4, showing the arrangement and operation of a gas jet system;

FIG. 6 is a diagrammatic cross section of an embodiment of a plasma processing system in accordance with principles of the invention;

FIG. 7 is a flow chart showing a method of processing a substrate in a plasma processing system in accordance with principles of the invention;

FIG. 8 is a flow chart showing a method of removing particles from a plasma processing system in accordance with principles of the invention;

FIG. 9 is a flow chart showing a method of removing particles from a plasma processing system in accordance with principles of the invention;

FIG. 10 is a flow chart showing a method of removing particles from a plasma processing system in accordance with principles of the invention; and

FIG. 11 is a flow chart showing a method of removing particles from a plasma processing system in accordance with principles of the invention.

### DETAILED DESCRIPTION OF EMBODIMENTS

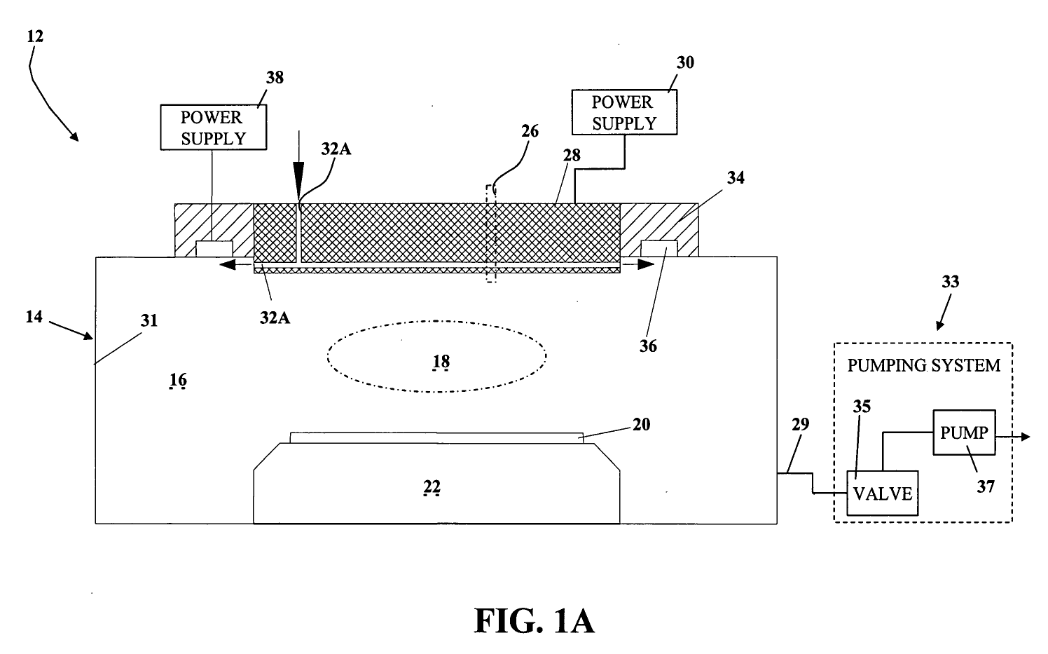

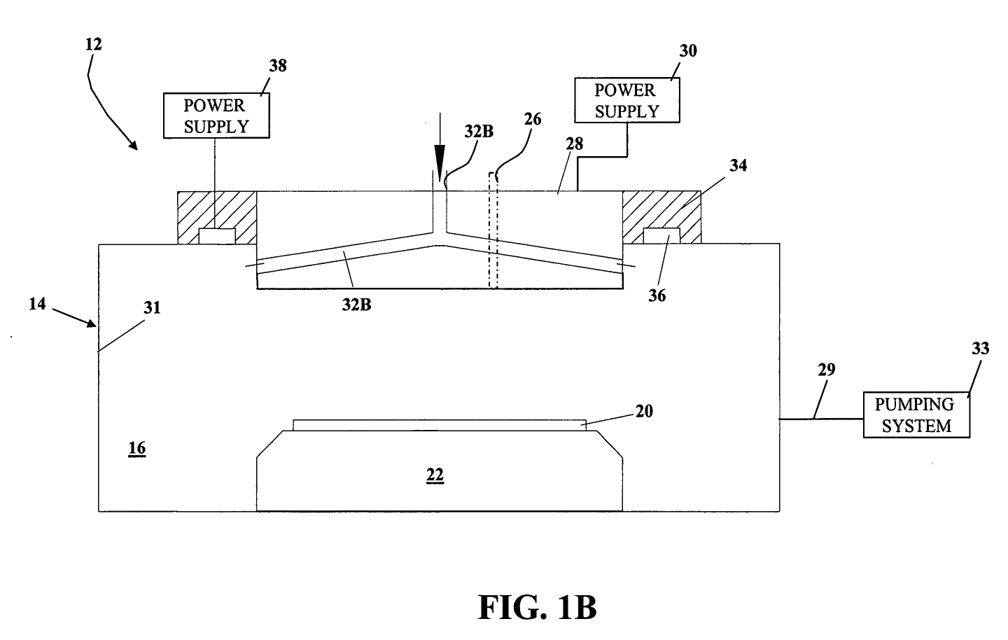

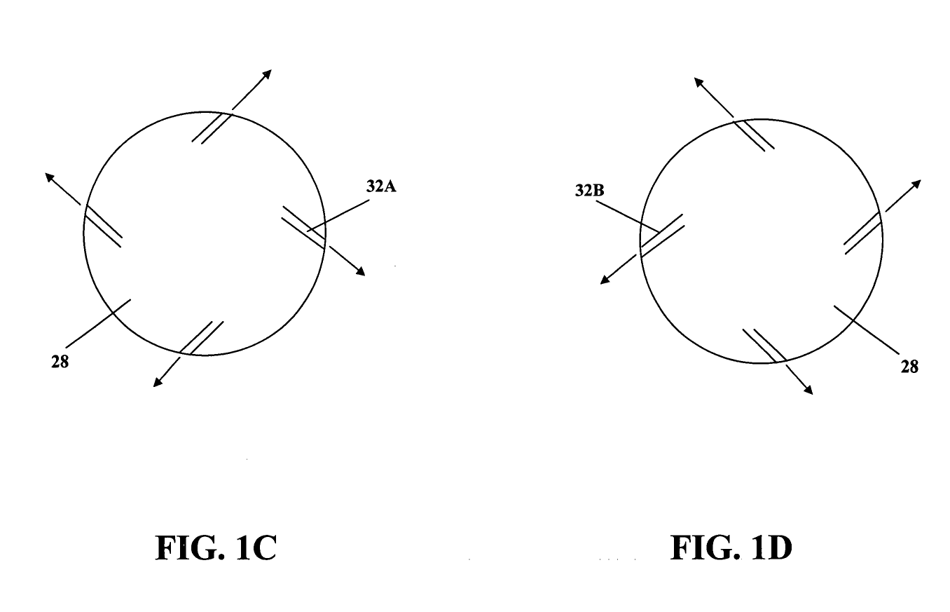

FIGS. 1A and 1B show an embodiment of a plasma processing system according to principles of the invention. The plasma processing system, generally indicated at 12, is schematically shown in FIGS. 1A and 1B. The plasma processing system 12 comprises a plasma process chamber, generally indicated at 14, that defines a plasma processing region 16 in which a plasma 18 can be generated. A chuck or electrode 22 can be positioned in the chamber 14 and is constructed and arranged to support a substrate 20 within the chamber 14 in the processing region 16. The substrate 20 can be a semiconductor wafer, integrated circuit, a sheet of a polymer material to be coated, a metal to be surface hardened by ion implantation, or some other material to be etched or deposited, for example.

Although not shown, coolant can be supplied to the chuck 22, for example, through cooling supply passages coupled to the chamber 14. Each cooling supply passage can be coupled to a cooling supply source. For example, the cooling supply passages can be individually connected to the cooling supply source. Alternatively, cooling supply passages can be interconnected by a network of interconnecting passages, which connect all cooling supply passages in some pattern.

Generally, plasma generation gas, which can be any gas that is ionizable to produce a plasma, is introduced into the chamber 14 to be made into a plasma, for example, through a gas inlet 26. The plasma generation gas can be selected according to the desired application as understood by one skilled in the art and can be nitrogen, xenon, argon, carbon tetrafluoride (CF₄) or octafluorocyclobutane (C₄F₈) for fluorocarbon chemistries, chlorine (Cl₂), hydrogen bromide (HBr), oxygen (O₂), or some other gas, for example.

The gas inlet 26 is coupled to the chamber 14 and is configured to introduce plasma processing gases into the plasma processing region 16. A variety of gas inlets or injectors and various gas injecting operations can be used to introduce plasma processing gases into the plasma process chamber 14, which can be hermetically sealed and can be formed from aluminum or another suitable material. The plasma processing gases are often introduced from gas injectors or inlets located adjacent to or opposite from the substrate. For example, as shown in FIGS. 1A and 1B, gases supplied through the gas inlet 26 can be injected through an inject electrode (upper electrode 28) opposite the substrate in a capacitively coupled plasma (CCP) source. The gases supplied through the gas inlet 26 can be controlled with a gas flow control system (not shown), for example.

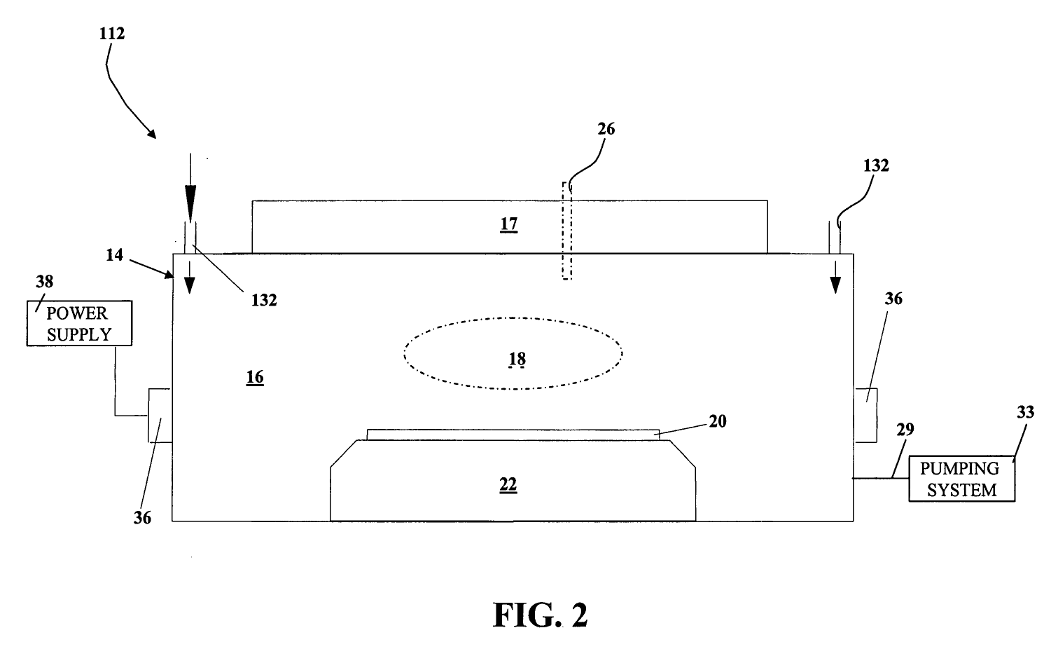

Alternatively, in embodiments not shown, the gases can be injected through a dielectric window opposite the substrate in a transformer coupled plasma (TCP) source. FIGS. 2-6 shows embodiments of the plasma processing system 12 in which the gases are injected through a gas inject plate in an inductively coupled plasma (ICP) source, for example, which will be described in greater detail below. Other gas injector arrangements are known to those skilled in the art and can be employed in conjunction with the plasma process chamber 14 as well as other plasma sources, such as Helicon and electron cyclotron resonance (ECR) sources, for example.

The plasma process chamber 14 can be fitted with an outlet 29 having a pumping system 33 attached thereto. A throttle control valve within pumping system 33 (shown as valve 35 coupled to the pumping system in FIG. 1A) can provide gas pressure control in the plasma process chamber 14. The pumping system 33 acts to remove particles from the vicinity of wafer 20. The gate valve 35 and a vacuum pump 37 (FIG. 1A) are components of the pumping system 33, but only the pumping system 33 is shown in FIGS. 2, 3, 4 and 6 for simplicity.

A plasma generator in the form of upper electrode 28 and lower electrode (or chuck) 22 may be coupled to the chamber 14 to generate the plasma 18 within the plasma processing region 16 by ionizing the plasma processing gases. The plasma processing gases can be ionized by supplying RF and/or DC power thereto, for example, with power supply 30 coupled to the upper electrode 28. In some applications, the plasma generator may contain an antenna or RF coil capable of supplying RF power, for example. The power supplied to the plasma, by power supply 30, for example, can ignite a discharge within the plasma generation gas introduced into the chamber 14, thus generating a plasma, such as plasma 18.

The upper electrode 28 can have one or more gas injection passages 32A (FIG. 1A) or 32B (FIG. 1B) formed therein. The passages 32A, 32B can be routed to the processing region 16 and can be supplied with purge gas from a supply of purge gas (not shown), e.g., an inert gas, separate from the gas injector 26. An inert gas such as helium, argon, krypton, neon, xenon and other gases or noble gases can be used for this purpose. The gas injection passages 32A, 32B can be formed in the upper electrode 28 so as to enter the processing region 16 of the chamber 14 in any direction or angle. In FIG. 1A, the gas injection passages 32A are configured to inject streams of purge gas in an outward radial direction toward an interior chamber wall 31 of the chamber 14. The gas injection passages 32A can be transverse to the interior chamber wall 31 and parallel to a plane defined by the substrate 20. The passages 32A can alternatively be arranged as shown in FIG. 1C so that purge gas motion has a centrifugal component which allows the purge gas to flow generally around the circumference of the interior chamber wall, which keeps particles flowing against the chamber wall and away from substrate 20. As shown in 1C, the passages 32A can be transverse to the interior chamber wall 31, e.g., at non-perpendicular angles relative to the interior chamber wall 31, and parallel to a plane defined by the substrate 20.

The gas injection passages 32B can be formed at non-perpendicular angles relative to the interior chamber wall 31 in the upper electrode 28 so that the injected purge gas has an upwards or downwards motion component (see FIG. 1B which shows a downwards motion component), and possibly also a swirl component (see FIG. 1D). In FIG. 1B, the gas injection passages 32B can be transverse to a plane defined by the substrate 20, while in FIG. 1D, the gas injection passages 32B can be parallel to the plane defined by the substrate 20. These injection angles help keep particles away from the wafer 20 by generating a flow pattern in the chamber that keeps the particles away from the wafer. For example, the swirl component can be generated by angling the passages 32A, 32B in a plane defined by the substrate, as shown in FIGS. 1C and 1D. The passages 32A, 32B can also be described as being angled relative to a horizontal plane with respect to a radius of the electrode 28. Alternatively, the passages 32A, 32B could be transverse to the interior chamber wall 31, e.g., angled at a non-perpendicular angles relative to the interior chamber wall 31.

An insulator ring 34 can substantially surround the upper electrode 28 and a DC or RF bias electrode 36 coupled to the chamber 14. For example, the electrode 36 can be embedded in an outer periphery of the insulator ring 34.

The DC or RF bias electrode 36 can be powered by an appropriate power supply 38. Pulsing of the electrode 36 can cause particles from a vicinity of the wafer 20 to be attracted to the vicinity of the electrode 36. Purge gas can then be passed through the passages 32A, 32B, either pulsed or continuously, into the processing region 16 to effect particle flow into the pumping system 33. In this manner, particles are removed from the chamber 14 and the processing region 16.

It is also possible to pulse the electrode 36 with an opposite polarity (e.g. for DC bias) than that used for attracting particles in addition to supplying purge gas through the gas injection passages 32A, 32B, to assist particle blow-off, e.g., removal of particles from the wafer vicinity. The opposite polarity terminates the attraction of the particles toward the electrode 36, facilitating particle removal with purge gas supplied through the gas injection passages 32A, 32B.

Various leads (not shown), for example, voltage probes or other sensors, can be coupled to the plasma processing system 12.

A controller (not shown) capable of generating control voltages sufficient to communicate and activate inputs to plasma processing system 12 as well as capable of monitoring outputs from the plasma processing system 12 can be coupled to the plasma processing system 14. For example, the controller can be coupled to and can exchange information with the RF power supply 30 of the upper electrode 28, respectively, and the gas inlet 26 (or flow control system in fluid communication therewith). The controller can further be in communication with the pumping system 33, and power supply 38 of electrode 36, respectively, as shown in FIGS. 1A and 1B. A program, which can be stored in a memory, may be utilized to control the aforementioned components of plasma processing system 12 according to a stored process recipe. Alternatively, multiple controllers can be provided, each of which is being configured to control different components of the plasma processing system 12, for example. One example of the controller is an embeddable PC computer type PC/104 from Micro/SYS of Glendale, Calif.

FIG. 2 shows a plasma processing system 112, which is of substantially similar construction and operation as the plasma processing system 12 shown in FIGS. 1A and 1B. Plasma reactor or generator 17 represents a “generic” plasma reactor, which may be any of a Capacitive Coupled Plasma (CCP) source, an Inductively Coupled Plasma (ICP) source, a Transformer Coupled Plasma (TCP) source, an Electron Cyclotron Resonance (ECR) plasma source, a helicon plasma source, or similar systems. The plasma processing system 112 comprises gas injection passages 132 that are formed through the wall of chamber 14 so as to be in communication with the processing region 16. Although the gas injection passages 132 are formed on a top wall of the chamber 14 in FIG. 2, the gas injection passages 132 can be formed in any wall of the chamber or reactor, e.g., wall 31 shown in FIGS. 1A and 1B, so that purge gas can be supplied to the processing region 16 in different directions or angles. FIG. 2 also shows the electrode 36 mounted on the side wall of plasma system 112. In different types of plasma systems or reactors, e.g. CCP, TCP, Helicon or ECR type systems or reactors, the electrode 36 can be mounted on any suitable wall of the chamber of such types of systems or reactors.

The electrode 36 can be biased to cause particles from the vicinity of the wafer 20 to be attracted to the vicinity of electrode 36 at an outer periphery of chamber 14. Purge gas can then be passed through passages 132 into the processing region 16 to effect particle flow into the pumping system 33. In this manner, particles are removed from the chamber 14 and the processing region 16.

As with the plasma processing system 12, the plasma processing system 112 can remove particles from the chamber 14 by pulsing the electrode 36 with an opposite polarity (e.g. for DC bias) than that used for attracting particles in addition to supplying purge gas through the gas injection passages 32.

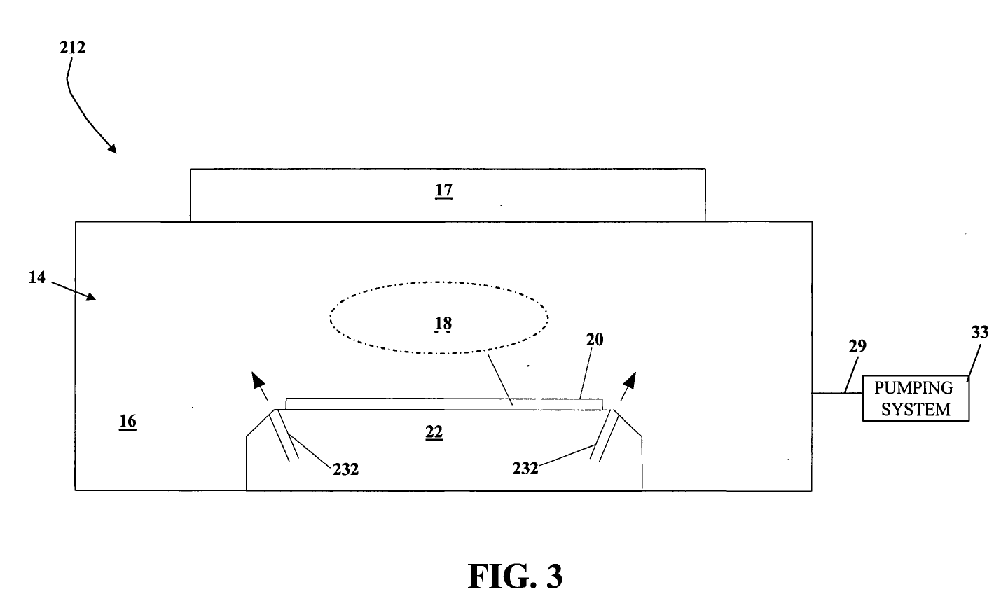

The plasma processing systems 12, 112 are illustrated using DC bias or RF bias in combination with a purge gas to remove particles from the processing region 16 of the chamber 14. Plasma processing system 212, which is shown in FIG. 3, is illustrated as using only purge gas to remove particles from the processing region 16 of chamber 14. Like parts in the plasma processing system 212 that are substantially identical in construction and operation as parts in plasma processing systems 12, 112 are labeled with similar reference numerals.

The plasma processing system 212 includes gas injection passages 232 that are formed in either the chuck 22 or a chuck pedestal structure upon which the chuck is positioned. The gas injection passages 232 are configured to jet streams of purge gas upward and outward away from the wafer 20. In the embodiment shown in FIG. 3, the purge gas can move particles away from the wafer, particularly the wafer's edge, by being supplied through the gas injection passages 232 simultaneously. The gas injection passages 232 can be formed on any of the above described plasma processing systems or reactors. Alternatively, purge gas can be supplied through the gas injection passages 232 continuously or can be passed through the gas injection passages 232 at different times.

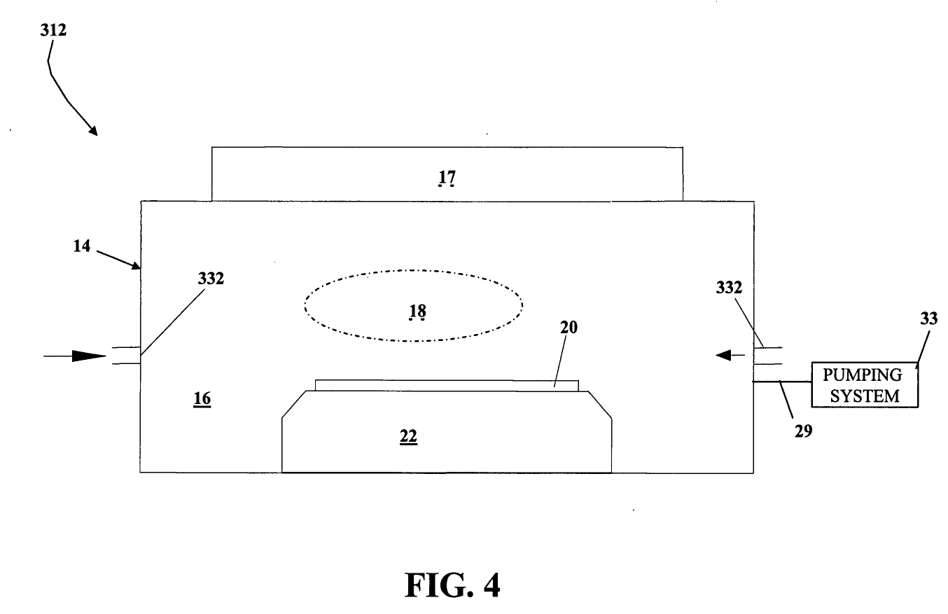

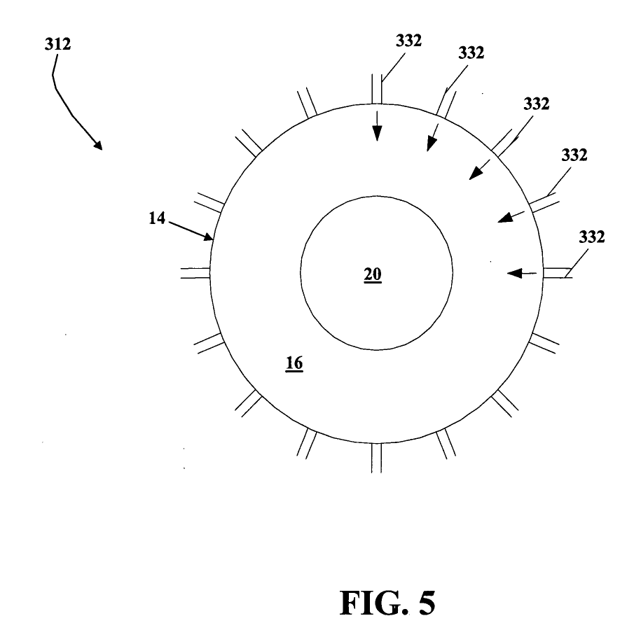

FIGS. 4 and 5 show a plasma processing system 312, which also is illustrated as using only purge gas to remove particles from the processing region 16 of the chamber 14. Like parts in the plasma processing system 312 that are substantially identical in construction and operation to parts of systems 12, 112 and 212 are labeled with similar reference numerals.

The plasma processing system 312 includes a particle removing system comprising gas injection passages 332 that are circumferentially positioned around the chamber 14 (FIG. 5). The gas injection passages 332 can be formed in the side walls of the chamber 14 such that streams of purge gas are directed over and above the wafer 20. The gas injection passages 332 can be operated in sets or zones, such that only one set or zone is pulsed at a time. For example, in FIG. 5, each set or zone could include 4 or 5 passages 332. In other words, one set or zone would span about a quarter of the circumference of the chamber 14, but a different number of zones and passages per zone may be used.

Activation of one set or zone can allow the gas flow and particles to avoid becoming stagnant near the wafer center. Thus, particles can be blown over the wafer 20, across the wafer center to the other side of the wafer 20, and removed through the pumping system 33. Multiple sets or zones of gas injection passages 332 can be operated sequentially, for example, so that each gas injection passage 332 is used at least one time.

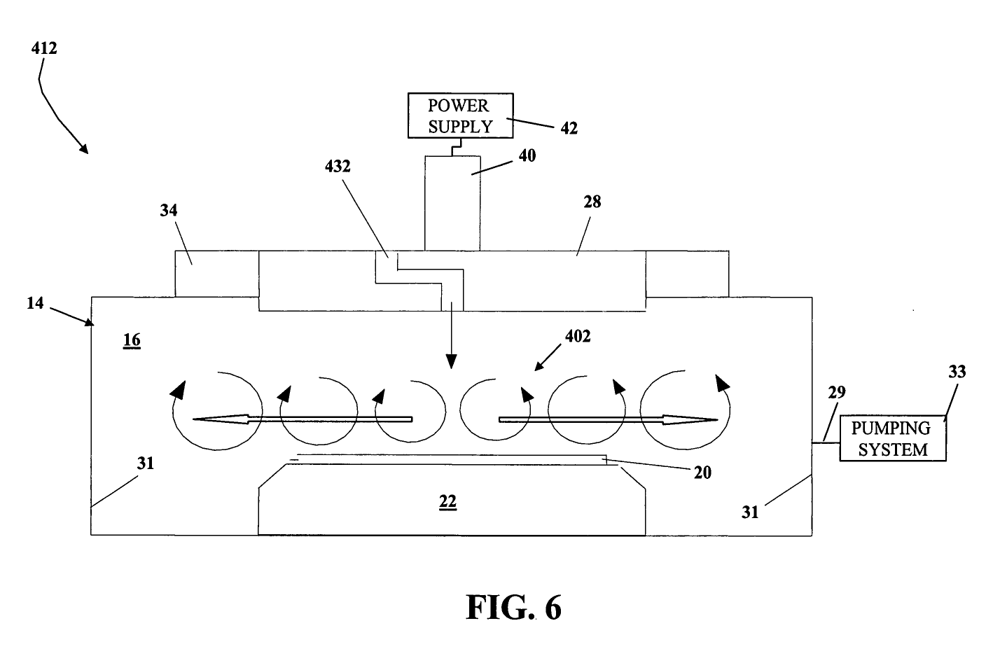

FIG. 6 shows plasma processing system 412, which also is illustrated as using only purge gas to remove particles from the procession region 16 of the chamber 14. Like parts in the plasma processing system 412 that are substantially identical in construction and operation to parts of systems 12, 112, 212 and 312 are labeled with similar reference numerals.

The plasma processing system 412 includes a gas injection passage 432 that is configured to produce an expanding vortex ring structure 402 as shown in FIG. 6 to facilitate removal of particles from the processing region 16 of the chamber 14.

Injecting gas in a pulse through passage 432 causes the creation of a gas flow vortex ring structure 402, which gradually expands radially and after some elapsed time reaches the interior chamber wall 31 (in directions indicated by the single-headed arrows), carrying with it particles suspended above the wafer 20.

In plasma processing systems, particles can typically be suspended above the wafer 20, and particularly the wafer edge, by electrostatic forces in the plasma 18. The particles generally do most damage to devices when the RF bias is removed from the chuck 22, or when the plasma 18 is turned off, which takes away the electrostatic potential that levitated the particles causing the particles to settle on the wafer 20 causing damage. In all of the embodiments described above, wafer processing can be performed according to a predetermined recipe, and before the plasma 18 is completely turned off, a low RF power operation, in which the plasma is still dense enough to keep the particles suspended while the plasma process has essentially stopped, can be used. During this low-power operation, the plasma processing systems 12, 112, 212, 312, 412 described above with respect to FIGS. 1A-D and 2-6, can be activated to remove the particles from the processing region 16 of the chamber 14. Once the particles have been pumped away with the pumping system 33, the RF power and plasma may be completely turned off. The plasma processing systems 12, 112, 212, 312, 412 described above with respect to FIGS. 1A-D and 2-6, can be activated to remove particles from the processing region 16 of the chamber 14 during wafer processing as well.

Although not shown, features of the plasma processing systems 12, 112, 212, 312, 412 described above with respect to FIGS. 1A-D and 2-6 can be mixed. More specifically, injection passage systems 32A, 32B, 132, 232, 332, 432 and electrode 36 can be substituted in any of the embodiments. For example, in plasma processing system 212, electrode 36 could be mounted on a side wall of the chamber 14 (as described above with respect to plasma processing system 112 shown in FIG. 2) to attract particles to the vicinity of the electrode 36 in addition to supplying purge gas through gas injection passages 232 on the side of chuck 22.

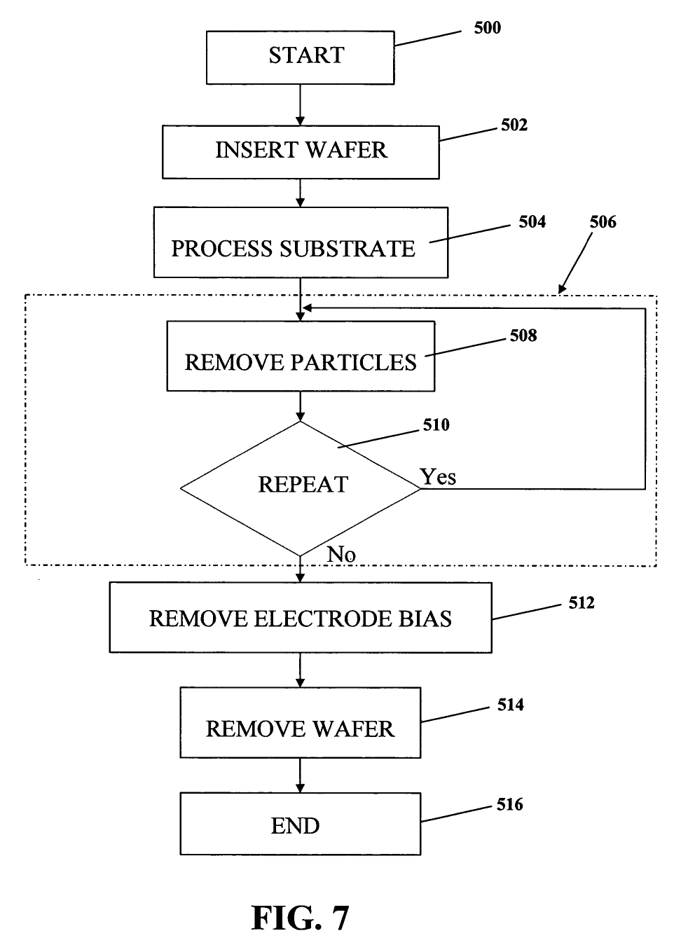

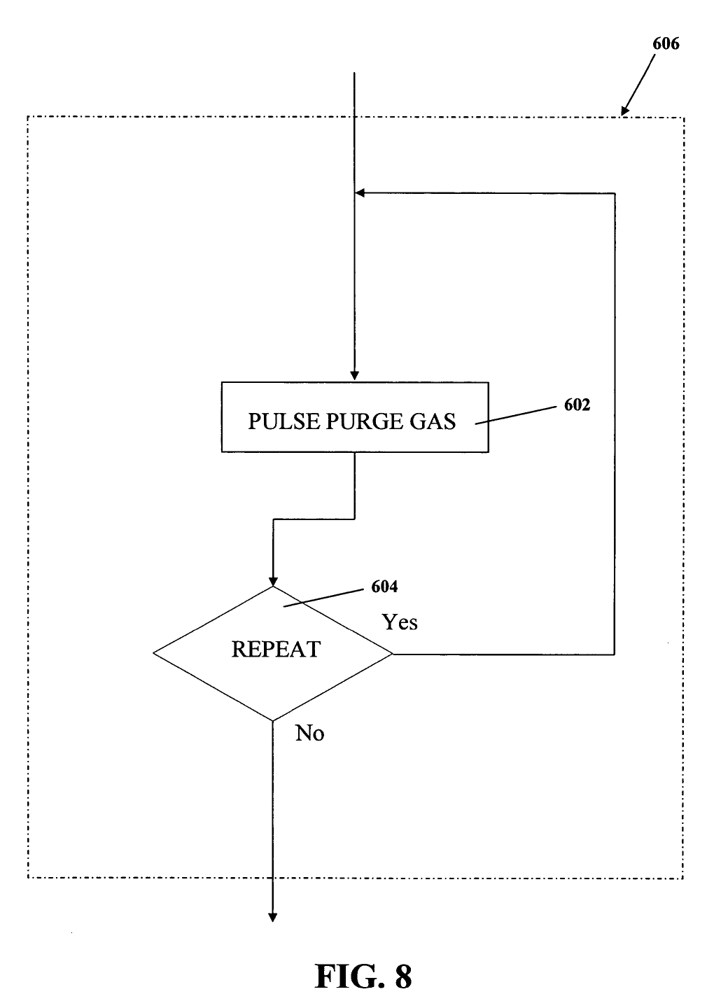

FIG. 7 shows a method of processing a substrate in a plasma processing system which can be used with any of the above described embodiments. FIGS. 8-11 show various methods of removing particles in a plasma processing system in accordance with principles of the invention and may be implemented in particular embodiment(s) described above.

The method of processing a substrate in a plasma processing system shown in FIG. 7 begins at 500. At 502, a wafer is positioned within a processing region of the plasma processing system. At 504, the wafer is processed according to a predetermined process recipe, as described above. Block 506 defines a particle removal sequence which includes removing particles at 508 and repeating the particle removal if necessary at 510. Although the block 506 follows the wafer processing of 504, the particle removal sequence can be performed during or after the wafer is processed according to the predetermined process recipe. FIGS. 8-11 show examples of operations which can be substituted into the above-described method shown in FIG. 7, in place of block 506.

At 508, particles are removed from the processing region of the process chamber using at least one of purge gas and electrostatic forces in the plasma. Particle removal can be repeated, if necessary, depending on the wafer process condition (e.g. for processes more prone to particle generation, multiple particle removal operations may be used). To this end, a determination is made at 510 whether or not to repeat the particle removal operation. If so, then the particle removal operation is repeated at 508 and another determination is made at 510. A predetermined number of removal operations can be made with the predetermined number being based on experience, experiments, yield and damage level, for example.

If a further particle removal operation is not necessary, then an electrical bias holding the wafer to the chuck is removed at 512. At 514, the processed wafer is removed from the plasma processing system. At 516, the method ends.

FIG. 8 shows block 606, which defines a particle removal sequence including pulsing a purge gas at 602 and repeating the pulsing if necessary at 604. The block 606 can be substituted into the above-described method shown in FIG. 7, in place of block 506 so that after or while the substrate is processed at 504, the purge gas is pulsed at 602. If the determination at 604 is that pulsing of the purge gas at 604 is necessary, then the purge gas will be pulsed at 602. If the determination at 604 is that further pulsing of the purge gas is not necessary, the sequence 606 ends, and continues at 512 of FIG. 7.

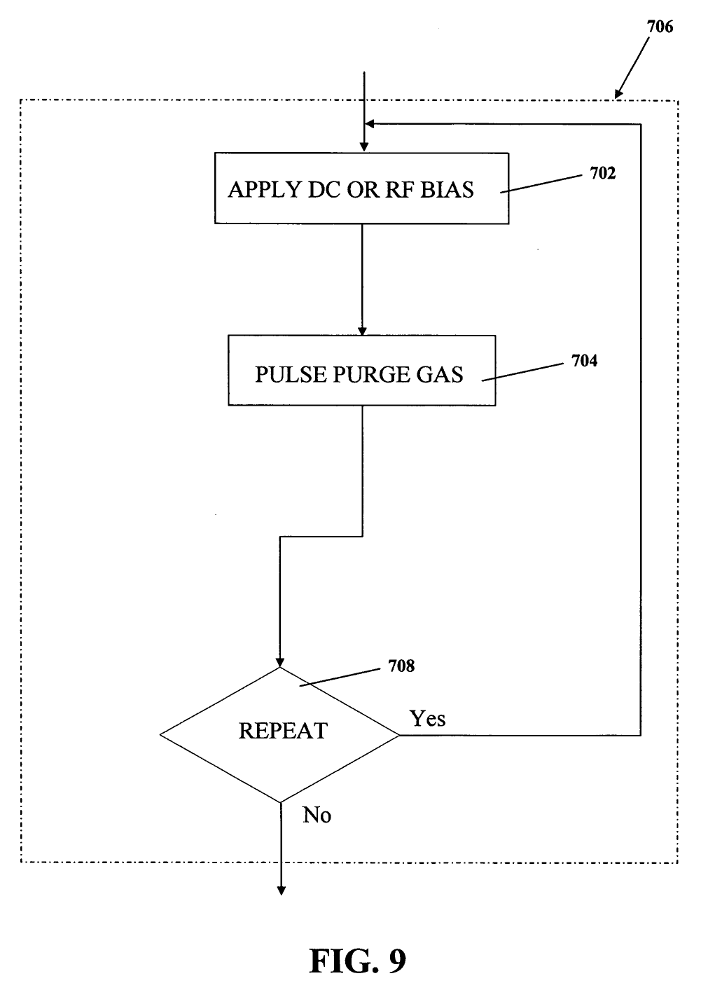

FIG. 9 shows block 706, which defines a particle removal sequence including applying a DC or RF bias to an electrode, such as, an electrode 36, for example, at 702. The particle removal sequence of block 706 also includes pulsing a purge gas at 704 and repeating the bias and gas pulsing if necessary at 708. The block 706 can be substituted into the above-described method shown in FIG. 7, in place of block 506 so that the DC or RF bias is applied to the electrode, for example, electrode 36 shown in FIGS. 1-2. If the determination at 708 is that further particle removal is necessary, then a DC or RF bias is applied at 702 and the purge gas will be pulsed at 704. If the determination at 708 is that further particle removal is not necessary, then the sequence 706 ends, and continues at 512 of FIG. 7.

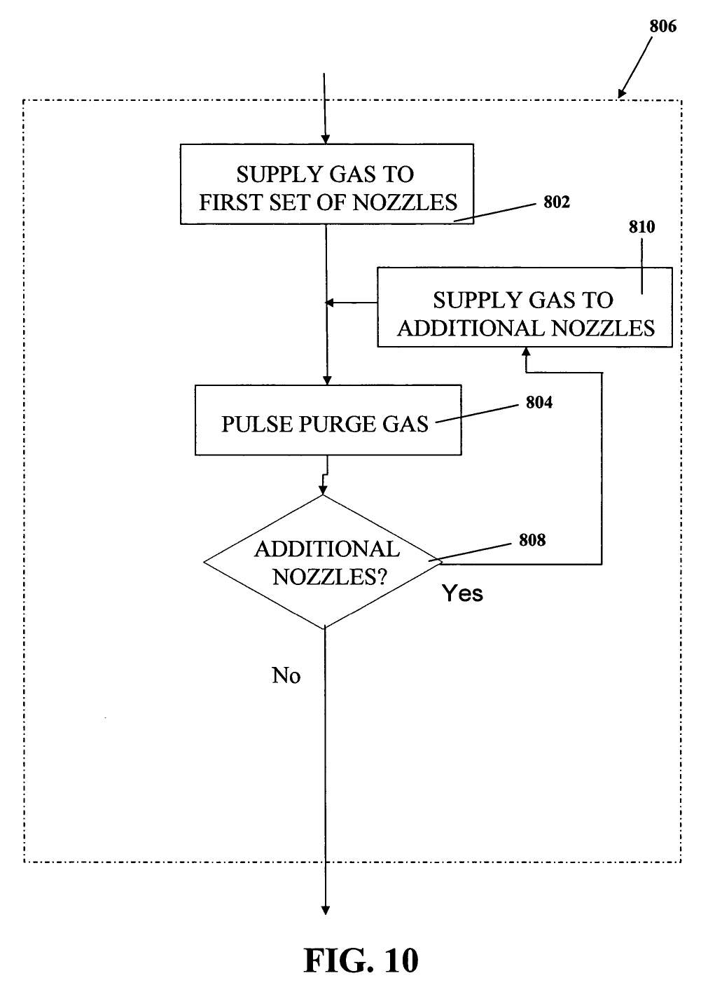

FIG. 10 shows block 806, which defines a particle removal sequence including supplying purge gas through a plurality of nozzles of gas injection passages that are positioned circumferentially around the plasma process chamber. This particle removal sequence can be used with plasma processing system 312 shown in FIGS. 4 and 5, for example. The first set of nozzles is connected to the gas supply system, e.g., by using a valve or a similar device, to supply gas to the first set of nozzles at 802, and the purge gas is pulsed at 804. A determination of whether purge gas pulsing is needed through an additional set of nozzles is made at 808. If needed, purge gas supply can be connected to additional nozzles, e.g., by using a valve or a similar device, to supply gas to the additional set of nozzles at 810, e.g., a second set of nozzles, and the pulsing of the purge gas at 804 is repeated with the second or additional set of nozzles. The process is repeated until all sets of nozzles have been pulsed. The nozzle sets can be pulsed in any order, and the sequence may include pulsing one set more times than others, within the sequence.

The block 806 can be substituted into the above-described method shown in FIG. 7, in place of block 506 so that after the substrate is processed at 504, purge gas is supplied through a plurality of nozzles of gas injection passages that are arranged circumferentially around the plasma processing chamber.

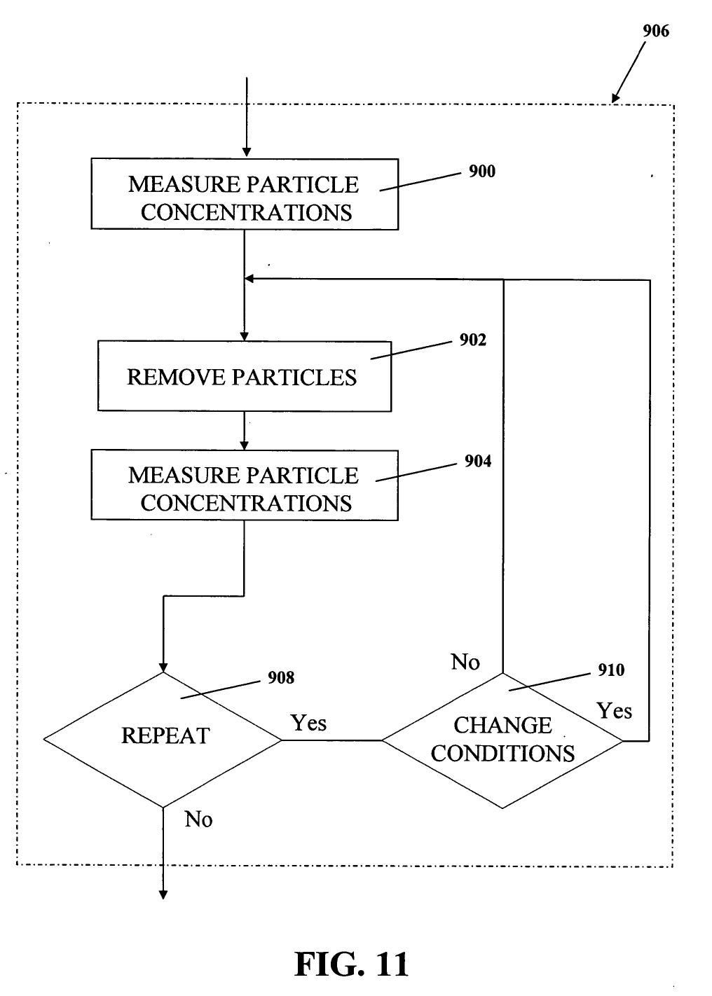

FIG. 11 shows block 906, which defines a particle removal sequence including measuring particle concentration in the process chamber at 900 and removing particles in the chamber at 902, using any of the methods shown in FIGS. 8, 9 or 10. Another measurement of particle concentration is performed in the process chamber at 904, after particle removal. The measurement of particle concentration can be performed in accordance with the teachings of U.S. Provisional Patent Application No. 60/429,067, filed Nov. 26, 2002, the contents of which are incorporated herein by reference in their entirety. Alternatively, any known method may be employed to measure particle concentration. At 908, a determination is made whether or not to repeat the particle removal. If so, then a determination is made at 910 whether or not particle removal conditions (e.g. purge gas flow, DC or RF electrode bias, or other conditions) need to be changed, which is optional (e.g. to change attraction, accelerate removal, etc.), and the removal operation is repeated at 902, followed by another particle concentration measurement at 904, and another decision to repeat at 908. Once the latest measurement confirms that particle concentration has been reduced to a safe level, all RF powers are cut-off, and the wafer is removed from the processing chamber (e.g. in flowchart of FIG. 7).

The block 906 can be substituted into the above-described method shown in FIG. 7, in place of block 506 so that after the substrate is processed at 504, particle concentration in the process chamber is measured at 900 and particles in the chamber are removed at 902, followed by another particle concentration measurement at 904. This last particle concentration measurement made can be correlated using statistical methods, to the damage due to particles during the process 504 of FIG. 7. Once a tolerable level of damage has been reached, the measured and correlated particle concentration can be used as a target value for other processes. In developing other processes, one can adjust parameters at 910, or the number of gas pulse repeats, until this target concentration is met, without necessarily evaluating the actual damage level at the wafer. This avoiding of measuring the actual damage level can save time during wafer process development.

The method can comprise additional acts, operations or procedures to remove particles from the plasma processing region added to the above methods for removing particles in plasma processing systems. Various combinations of these additional acts, operations or procedures could be used as well. For example, operations to remove particles from the plasma processing chamber can be performed during substrate processing or after the substrate is processed.

While the present invention has been particularly shown and described with reference to the preferred embodiments thereof, it will be understood by those skilled in the art that various changes in form and details can be made therein without departing from the spirit and scope of the invention.

For example, a particle measurement system could be used with any one of the plasma processing systems 12, 112, 212, 312 or 412 described in FIGS. 1A, 1B and 2-6. The particle measurement system could be coupled to the processing chamber 14 to read particle concentrations therein. The particle concentration data could be used to determine when, and if, the plasma processing system 12, 112, 212, 312 or 412 or the plasma processing chamber 14 requires cleaning, for example. Thus, the plasma processing system 12, 112, 212, 312 or 412 or the plasma processing chamber 14 can be cleaned only when necessary, which can improve typical yields, and increase time between preventive maintenance shutdowns of the plasma processing system 12, 112, 212, 312 or 412. It also allows the process engineer to adjust the process parameters so that particle generation is minimized, if that is necessary for some particularly sensitive process, e.g. the system provides the measurements that allow various process recipes to be compared.

Thus, the foregoing embodiments have been shown and described for the purpose of illustrating the functional and structural principles of this invention and are subject to change without departure from such principles. Therefore, this invention includes all modifications encompassed within the spirit and scope of the following claims.

What is claimed is:

1. A plasma processing system comprising:
a chamber containing a plasma processing region;
a chuck, configured to support a substrate within the chamber in the processing region;
a plasma generator in communication with the chamber, the plasma generator being configured to generate a plasma during a plasma process in the plasma processing region; and
at least one gas injection passage in communication with the chamber and configured to facilitate removal of particles from the chamber by passing purge gas therethrough.

2. The plasma processing system of claim 1, further comprising a pumping system coupled to the chamber to remove particles from the chamber.

3. The plasma processing system of claim 1, further comprising an electrode configured to attract or repel particles in the chamber by electrostatic force when the electrode is biased with DC or RF power.

4. The plasma processing system of claim 3, wherein the plasma generator includes an upper electrode.

5. The plasma processing system of claim 4, further comprising an insulation member disposed in surrounding relation to the upper electrode.

6. The plasma processing system of claim 5, wherein the at least one gas injection passage is formed in the upper electrode.

7. The plasma processing system of claim 5, wherein the electrode is positioned within the insulating member.

8. The plasma processing system of claim 1, further comprising a particle measurement system coupled to the chamber.

9. The plasma processing system of claim 8, further comprising an electrode configured to attract or repel particles in the chamber when the electrode is biased with DC or RF power.

10. The plasma processing system of claim 9, wherein the electrode is mounted on a side wall of the chamber.

11. The plasma processing system of claim 10, wherein the at least one gas injection passage is formed in an upper wall of the chamber.

12. The plasma processing system of claim 11, wherein the electrode is configured to attract particles thereto such that the gas injection passage can supply purge gas to remove the attracted particles from the chamber.

13. The plasma processing system of claim 1, wherein the at least one gas injection passage is formed in the chuck, so as to be directed in an upward direction generally outwardly of the substrate supported on the chuck.

14. The plasma processing system of claim 1, wherein the at least one gas injection passage includes a plurality of passages arranged in circumferential relation about the chamber.

15. The plasma processing system of claim 14, wherein the plurality of passages are divided into multiple sets, each set being actuated at a different time to facilitate removal of particles from the chamber.

16. The plasma processing system of claim 3, wherein the electrode is biased to attract particles thereto and is subsequently biased to terminate the attraction of particles thereto, such that the gas injection passage can supply purge gas to remove the particles from the chamber when the attraction of particles to the electrode is terminated.

17. The plasma processing system of claim 1, wherein the at least one gas injection passage is configured to inject purge gas having a swirl component that helps keep particles away from the substrate by giving the particles a swirl velocity component.

18. The plasma processing system of claim 1, wherein the at least one gas injection passage is transverse to a plane defined by the substrate.

19. The plasma processing system of claim 1, wherein the at least one gas injection passage is transverse to an interior wall of the chamber and parallel to a plane defined by the substrate.

20. The plasma processing system of claim 1, wherein the at least one gas injection passage is angled at a non-perpendicular angle relative to an interior wall of the chamber.

21. The plasma processing system of claim 1, wherein the at least one gas injection passage is angled at a non-perpendicular angle relative to a plane defined by the substrate.

22. The plasma processing system of claim 1, wherein the purge gas includes an inert gas or a noble gas.

23. A method of processing a substrate in a plasma processing system having a chamber containing a plasma processing region in which a plasma can be generated during a plasma process to process the substrate, the method comprising:
removing particles in the chamber, the removing comprising supplying purge gas through at least one gas injection passageway in communication with the chamber.

24. The method of claim 23, wherein the removing of particles comprises continuously supplying purge gas through the at least one gas injection passageway.

25. The method of claim 23, wherein the removing of particles comprises
supplying purge gas through a plurality of gas injection passages arranged in circumferential relation around the chamber, each passage including a nozzle for injecting a purge gas into the chamber.

26. The method of claim 23, wherein the removing of particles further comprises
supplying purge gas through a first set of the plurality of gas injection passages so that respective nozzles of the first set of passages inject purge gas into the chamber; and
supplying purge gas through a second set of the plurality of gas injection passages so that respective nozzles of the second set of passages inject purge gas into the chamber at a different time than the first set of passages.

27. The method of claim 23, wherein the removing of particles further comprises
measuring particle concentration in the chamber with a particle measurement system; and
repeating the removing of particles in the chamber based on the measured particle concentration.

28. The method of claim 23, wherein the removing of particles comprises energizing an electrode configured to attract or repel particles in the chamber.

29. The method of claim 23, further comprising energizing an electrode configured to attract particles in the chamber toward the electrode from the substrate and supplying the purge gas to remove the attracted particles from the chamber.

30. The method of claim 29, further comprising energizing the electrode to terminate the attraction of particles in the chamber toward the electrode and supplying the purge gas to remove the particles from the chamber.

31. The method of claim 23, wherein the removing of particles is performed after the substrate has been processed.
